(19) United States
(12) Patent Application Publication
(10) Pub. No.: US 2026/0359525 A1
(43) Pub. Date: Nov. 12, 2026

(54) APPARATUS FOR GENERATING MECHANICAL-ELECTRICAL-PLUMBING ROUTING PATH BASED ON ARTIFICIAL INTELLIGENCE AND METHOD FOR CONTROLLING SAME

(71) Applicants: Jae Heon JUNG, Seoul (KR); Yu Mi LEE, Incheon (KR); SLZ Inc., Siheung-si (KR)

(72) Inventors: Jae Heon JUNG, Seoul (KR); Yu Mi LEE, Incheon (KR)

(73) Assignees: Jae Heon JUNG, Seoul (KR); Yu Mi LEE, Incheon (KR); SLZ Inc., Siheung-si, Gyeonggi-do (KR)

(21) Appl. No.: 19/574,816

(22) Filed: Mar. 23, 2026

(30) Foreign Application Priority Data
May 7, 2025 (KR) 10-2025-0059172

(51) Int. Cl. G06F 30/27; G06F 30/18

(52) U.S. Cl. CPC G06F 30/27; G06F 30/18

(57) ABSTRACT

An apparatus for generating a Mechanical-Electrical-Plumbing (MEP) routing path based on artificial intelligence (AI) and a method for controlling the same are provided. The apparatus based on AI includes at least one memory configured to store at least one process for performing operations of inferring a design rule and predicting an MEP routing path using an as-built drawing, and a processor configured to perform the operations of inferring the design rule and predicting the MEP routing path using the as-built drawing based on the at least one process. The processor is configured to receive the as-built drawing, input the as-built drawing as an input value to a pre-trained AI model to receive the MEP routing path as an output value, and perform reinforcement learning on an algorithm by which the AI model infers the design rule through the as-built drawing, using a pre-stored design rule.

### CROSS-REFERENCE TO RELATED APPLICATIONS

A claim for priority under 35 U.S.C. § 119 is made to Korean Patent Application No. 10-2025-0059172 filed on May 7, 2025 in the Korean Intellectual Property Office, the entire contents of which are hereby incorporated by reference.

### BACKGROUND

### 1. Technical Field

The present disclosure relates to an apparatus for generating a Mechanical-Electrical-Plumbing (MEP) routing path and a method for controlling the same. More particularly, the present disclosure relates to an artificial intelligence (AI)-based apparatus for generating an MEP routing path and a method for controlling the same.

### 2. Description of Related Art

Design engineering technology required for the maintenance of MEP (Mechanical, Electrical, Plumbing) in industrial plants is operated with a focus on field conditions. This is because replacement or maintenance issues must be resolved in an “as-built” situation. Here, an as-built drawing refers to a drawing or a model that reflects the actually constructed state after a construction project is completed. Unlike initial design drawings, they include changes or modifications and provides important information for building maintenance and additional construction.

That is, the as-built situation may refer to a state in which the form, structure, and all changes of the actually constructed facility are reflected.

However, since existing drawings exist in a 2D CAD format and are not in the form of Building Information Modeling (BIM) data (models, information, drawings), which are three-dimensional drawings, it is difficult to perform activities such as maintenance with only the drawings.

Most design rules (or design logic) are formed as implicit knowledge as empirical assets, and there are many parts that are not organized into formulas. In addition, there is a problem in that it is difficult to formalize and standardize because different rule sets (design rules) are applied to each field.

Accordingly, there is a need for agents capable of inferring existing design rules in an as-built situation.

### SUMMARY

An object of an embodiment disclosed in the present disclosure is to provide an apparatus for generating an MEP routing path based on AI and a method for controlling the same, which are capable of inferring a design rule from an as-built drawing and generating an MEP routing path in an optimized manner.

The technical problems to be solved by the present disclosure are not limited to the above-mentioned problems, and other problems not mentioned will be clearly understood by those skilled in the art from the following description.

In order to achieve the above-described technical tasks, an apparatus for generating an MEP routing path based on AI according to the present disclosure includes: at least one memory configured to store at least one process for performing operations of inferring a design rule and predicting an MEP routing path using an as-built drawing; and a processor configured to perform the operations of inferring the design rule and predicting the MEP routing path using the as-built drawing based on the at least one process, wherein the processor is configured to receive the as-built drawing, input the as-built drawing as an input value to a pre-trained AI model to receive the MEP routing path as an output value, and perform reinforcement learning on an algorithm by which the AI model infers the design rule through the as-built drawing, using a pre-stored design rule.

According to an embodiment, the processor may include a graph generator configured to convert the input as-built drawing into a graph format to be usable in the AI model.

According to an embodiment, the graph generator may analyze the as-built drawing to generate a BIM hierarchy graph, and input the BIM hierarchy graph as the input value to the pre-trained AI model.

According to an embodiment, the graph generator may calculate summarized physical information from the BIM hierarchy graph.

According to an embodiment, the pre-trained AI model may be a model supervisedly trained using an as-built drawing dataset as training data and a ground-truth MEP routing path as a result value.

According to an embodiment, the pre-trained AI model may be configured to, when the as-built drawing is input, infer a design rule applied to the as-built drawing and generate the MEP routing path based on the inferred design rule.

According to an embodiment, the design rule may include at least one of a design priority, a waypoint, a limit on the number of direction changes, and a length limit.

According to an embodiment, the processor may perform reinforcement learning on a design rule inference algorithm of the pre-trained AI model by using the as-built drawing dataset as a training dataset and the pre-stored design rule as a ground-truth value.

According to an embodiment, the processor may include a learning tool configured to infer the design rule from the as-built drawing, and may input the BIM hierarchy graph output from the graph generator and the design rule inferred by the learning tool as input values to the AI model to receive the MEP routing path as the output value.

A method for controlling an apparatus for generating an MEP routing path based on AI according to the present disclosure may include: receiving an as-built drawing; inputting the as-built drawing as an input value to a pre-trained AI model to receive an MEP routing path as an output value; and performing reinforcement learning on an algorithm by which the AI model infers a design rule through the as-built drawing, using a pre-stored design rule.

In addition, a computer program stored in a computer-readable recording medium for implementing the present disclosure may be further provided.

In addition, a computer-readable recording medium for recording a computer program for implementing the present disclosure may be further provided.

### BRIEF DESCRIPTION OF THE FIGURES

FIG. 1 is a block diagram of an apparatus for generating a Mechanical-Electrical-Plumbing (MEP) routing path based on artificial intelligence (AI) according to the present disclosure.

FIG. 2 is a flowchart illustrating a representative control method of the present disclosure.

FIGS. 3, 4, 5, 6, 7, 8, and 9 are conceptual diagrams for describing the control method illustrated in FIG. 2.

### DETAILED DESCRIPTION

Throughout the present disclosure, the same reference numerals refer to the same components. This disclosure does not describe all elements of the embodiments, and descriptions common in the technical field to which the present disclosure pertains or overlapping descriptions between the embodiments will be omitted. The terms “unit, module, member, and block” used in the specification may be implemented as software or hardware, and depending on the embodiments, a plurality of “units, modules, members, or blocks” may be implemented as a single component, or a single “unit, module, member, or block” may include a plurality of components.

Throughout the specification, when a part is said to be “connected” to another part, this includes not only a case of being directly connected but also a case of being indirectly connected, and the indirect connection includes connection through a wireless communication network.

In addition, when a part is said to “include” a component, this means that it may further include other components rather than excluding other components unless specifically stated otherwise.

Throughout the specification, when a member is said to be “on” another member, this includes not only a case where the member is in contact with the other member but also a case where another member exists between the two members.

Terms such as first and second are used to distinguish one component from another component, and the components are not limited by the aforementioned terms.

Singular expressions include plural expressions unless the context clearly indicates otherwise.

In each step, identification codes are used for convenience of explanation, and the identification codes do not describe the order of the steps. Each step may be performed in an order different from the specified order unless a specific order is clearly described in the context.

Hereinafter, the operation principles and embodiments of the present disclosure will be described with reference to the accompanying drawings.

In the present specification, “an apparatus according to the present disclosure” includes all of various devices capable of providing a result to a user by performing computational processing. For example, the apparatus according to the present disclosure may include all of a computer, a server device, and a portable terminal, or may be in any one form.

Here, the computer may include, for example, a laptop, a desktop, a laptop, a tablet PC, a slate PC, and the like, equipped with a web browser.

The server device is a server that processes information by communicating with an external device, and may include an application server, a computing server, a database server, a file server, a game server, a mail server, a proxy server, a web server, and the like.

The portable terminal is, for example, a wireless communication device for which portability and mobility are guaranteed, and may include all kinds of handheld-based wireless communication devices such as Personal Communication System (PCS), Global System for Mobile communications (GSM), Personal Digital Cellular (PDC), Personal Handyphone System (PHS), Personal Digital Assistant (PDA), International Mobile Telecommunication (IMT)-2000, Code Division Multiple Access (CDMA)-2000, W-Code Division Multiple Access (W-CDMA), Wireless Broadband Internet (WiBro) terminal, smart phone, etc., and wearable devices such as a watch, a ring, a bracelet, an anklet, a necklace, glasses, contact lenses, or a head-mounted-device (HMD).

Functions related to artificial intelligence according to the present disclosure are operated through a processor and a memory. The processor may be composed of one or a plurality of processors. In this case, the one or a plurality of processors may be a general-purpose processor such as a CPU, an AP, or a Digital Signal Processor (DSP), a graphics-only processor such as a GPU or a Vision Processing Unit (VPU), or an AI-dedicated processor such as an NPU. The one or a plurality of processors control to process input data according to a pre-defined operation rule or an AI model stored in the memory. Alternatively, when the one or a plurality of processors are AI-dedicated processors, the AI-dedicated processor may be designed with a hardware structure specialized for processing a specific AI model.

The pre-defined operation rule or the AI model is characterized by being created through learning. Here, being created through learning means that a basic AI model is trained using a plurality of pieces of training data by a learning algorithm, so that a pre-defined operation rule or an AI model set to perform a desired characteristic (or purpose) is created. Such learning may be performed in the device itself in which the AI according to the present disclosure is performed, or may be performed through a separate server and/or system. Examples of learning algorithms include supervised learning, unsupervised learning, semi-supervised learning, or reinforcement learning, but are not limited to the aforementioned examples.

The AI model may be composed of a plurality of neural network layers. Each of the plurality of neural network layers has a plurality of weight values, and performs a neural network operation through an operation between an operation result of a previous layer and the plurality of weight values. The plurality of weight values possessed by the plurality of neural network layers may be optimized by a learning result of the AI model. For example, the plurality of weight values may be updated such that a loss value or a cost value obtained in the AI model during a learning process is reduced or minimized. The artificial neural network may include a Deep Neural Network (DNN), and examples thereof include Convolutional Neural Network (CNN), Deep Neural Network (DNN), Recurrent Neural Network (RNN), Restricted Boltzmann Machine (RBM), Deep Belief Network (DBN), Bidirectional Recurrent Deep Neural Network (BRDNN), or Deep Q-Networks, but are not limited to the aforementioned examples.

According to an exemplary embodiment of the present disclosure, the processor may implement AI. AI refers to a machine learning method based on an Artificial Neural Network that imitates a human biological neuron to allow a machine to learn. Methodologies of AI can be divided into supervised learning in which an answer (output data) to a problem (input data) is determined by providing input data and output data together as training data according to a learning method; unsupervised learning in which only input data is provided without output data so that an answer to a problem is not determined; and reinforcement learning in which a reward is given from an external environment whenever a certain action is taken in a current state, and learning is performed in a direction to maximize such a reward. In addition, the methodology of AI may be classified according to an architecture that is a structure of a learning model. Architectures of widely used deep learning technologies may be classified into Convolutional Neural Network (CNN), Recurrent Neural Network (RNN), Transformer, Generative Adversarial Networks (GAN), and the like.

The present apparatus and system may include an AI model. The AI model may be a single AI model or may be implemented as a plurality of AI models. The AI model may be composed of a neural network (or an artificial neural network), and may include a statistical learning algorithm that imitates a biological nerve in machine learning and cognitive science. The neural network may refer to an overall model having a problem-solving ability by changing the connection strength of synapses through learning by artificial neurons (nodes) forming a network by the combination of synapses. A neuron of a neural network may include a combination of weights or biases. The neural network may include one or more layers composed of one or more neurons or nodes. For example, the apparatus may include an input layer, a hidden layer, and an output layer. The neural network constituting the apparatus can infer a result (output) to be predicted from an arbitrary input by changing weights of neurons through learning.

The processor may generate a neural network, train (or learn) a neural network, perform an operation based on received input data, generate an information signal based on a result of the performance, or retrain a neural network. Models of the neural network may include various types of models such as CNN (Convolutional Neural Network) such as GoogleNet, AlexNet, VGG Network, etc., R-CNN (Region with Convolutional Neural Network), RPN (Region Proposal Network), RNN (Recurrent Neural Network), S-DNN (Stacking-based deep Neural Network), S-SDNN (State-Space Dynamic Neural Network), Deconvolution Network, DBN (Deep Belief Network), RBM (Restricted Boltzmann Machine), Fully Convolutional Network, LSTM (Long Short-Term Memory) Network, Classification Network, etc., but are not limited thereto. The processor may include one or more processors for performing operations according to the models of the neural network. For example, the neural network may include a Deep Neural Network.

Those skilled in the art will understand that the neural network may include any neural network, including but not limited to CNN (Convolutional Neural Network), RNN (Recurrent Neural Network), perceptron, multilayer perceptron, FF (Feed Forward), RBF (Radial Basis Network), DFF (Deep Feed Forward), LSTM (Long Short Term Memory), GRU (Gated Recurrent Unit), AE (Auto Encoder), VAE (Variational Auto Encoder), DAE (Denoising Auto Encoder), SAE (Sparse Auto Encoder), MC (Markov Chain), HN (Hopfield Network), BM (Boltzmann Machine), RBM (Restricted Boltzmann Machine), DBN (Deep Belief Network), DCN (Deep Convolutional Network), DN (Deconvolutional Network), DCIGN (Deep Convolutional Inverse Graphics Network), GAN (Generative Adversarial Network), LSM (Liquid State Machine), ELM (Extreme Learning Machine), ESN (Echo State Network), DRN (Deep Residual Network), DNC (Differentiable Neural Computer), NTM (Neural Turing Machine), CN (Capsule Network), KN (Kohonen Network), and AN (Attention Network).

According to an exemplary embodiment of the present disclosure, the processor may use various AI structures and algorithms, such as CNN (Convolutional Neural Network) such as GoogleNet, AlexNet, VGG Network, etc., R-CNN (Region with Convolutional Neural Network), RPN (Region Proposal Network), RNN (Recurrent Neural Network), S-DNN (Stacking-based deep Neural Network), S-SDNN (State-Space Dynamic Neural Network), Deconvolution Network, DBN (Deep Belief Network), RBM (Restricted Boltzmann Machine), Fully Convolutional Network, LSTM (Long Short-Term Memory) Network, Classification Network, Generative Modeling, eXplainable AI, Continual AI, Representation Learning, AI for Material Design, BERT for natural language processing, SP-BERT, MRC/QA, Text Analysis, Dialog System, GPT-3, GPT-4, Visual Analytics for vision processing, Visual Understanding, Video Synthesis, ResNet, Anomaly Detection for data intelligence, Prediction, Time-Series Forecasting, Optimization, Recommendation, Data Creation, etc., but is not limited thereto. Hereinafter, embodiments of the present disclosure will be described in detail with reference to the accompanying drawings.

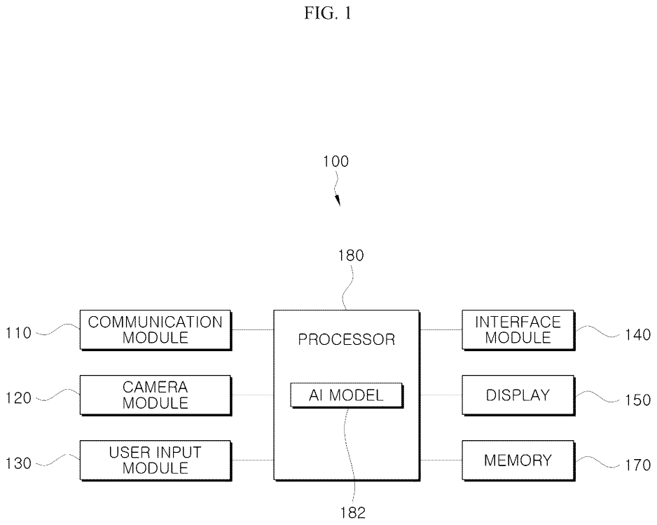

FIG. 1 is a block diagram of an apparatus for generating an MEP routing path based on AI according to the present disclosure.

An apparatus 100 for generating an MEP routing path based on AI according to the present disclosure can automatically generate an MEP routing path by inferring a design rule using an as-built drawing (As-Built design information or BIM information). In addition, the apparatus 100 of the present disclosure may perform automatic routing through reinforcement learning using a given design rule without separate As-Built design information.

To this end, the apparatus 100 of the present disclosure may include a communication module 110, a camera module 120, a user input module 130, an interface module 140, a display 150, a memory 170, and a processor 180 including an AI model 182.

The components shown in FIG. 1 are not essential in implementing the apparatus 100 according to the present disclosure, so the apparatus 100 described in the present specification may have more or fewer components than the components listed above.

The communication module 110 may include one or more components that enable communication with an external device, and for example, may include at least one of a broadcast reception module, a wired communication module, a wireless communication module, a short-range communication module, and a location information module.

The wireless communication module may include a wireless communication module supporting various wireless communication schemes such as GSM (global System for Mobile Communication), CDMA (Code Division Multiple Access), WCDMA (Wideband Code Division Multiple Access), UMTS (universal mobile telecommunications system), TDMA (Time Division Multiple Access), LTE (Long Term Evolution), 4G, 5G, and 6G, in addition to a Wi-Fi module and a WiBro (Wireless broadband) module.

The location information module is a module for obtaining the location (or current location) of the apparatus according to the present disclosure, and representative examples thereof include a GPS (Global Positioning System) module or a Wi-Fi (Wireless Fidelity) module. For example, when a GPS module is utilized, the location of the present apparatus can be obtained using a signal transmitted from a GPS satellite. As another example, when a Wi-Fi module is utilized, the location of the present apparatus can be obtained based on information of a wireless AP (Wireless Access Point) that transmits or receives a wireless signal with the Wi-Fi module. If necessary, the location information module may perform any function among other modules of the communication unit to alternatively or additionally obtain data regarding the location of the present apparatus. The location information module is a module used to obtain the location (or current location) of the present apparatus, and is not limited to a module that directly calculates or obtains the location of the present apparatus.

The camera module 120 processes an image frame such as a still image or a moving image obtained by an image sensor in a shooting mode. The processed image frame may be displayed on the display or stored in the memory.

Meanwhile, when there are a plurality of camera modules, they may be disposed to form a matrix structure. A plurality of pieces of image information having various angles or focuses can be input through the cameras forming the matrix structure. Also, the cameras may be disposed in a stereo structure to obtain a left image and a right image for implementing a 3D stereoscopic image.

The user input module 130 is for receiving information from a user. When information is input through the user input module, the processor can control the operation of the present apparatus to correspond to the input information. Such a user input module may include a hardware-type physical key (e.g., a button, a dome switch, a jog wheel, a jog switch, etc., disposed on at least one of the front, back, and side of the present apparatus) and a software-type touch key. As an example, the touch key may consist of a virtual key, a soft key, or a visual key displayed on a touch screen type display unit through software processing, or may consist of a touch key disposed in a part other than the touch screen. Meanwhile, the virtual key or visual key may be displayed on the touch screen in various forms, and for example, may consist of graphics, text, icons, video, or a combination thereof.

The interface module 140 serves as a path to various types of external devices connected to the present apparatus. Such an interface module may include at least one of a wired/wireless headset port, an external charger port, a wired/wireless data port, a memory card port, a port for connecting a device equipped with an identification module (SIM), an audio I/O (Input/Output) port, a video I/O (Input/Output) port, and an earphone port. In the present apparatus, appropriate control related to an external device connected to the interface module can be performed.

The display 150 displays (outputs) information processed in the present apparatus. For example, the display unit may display execution screen information of an application program (for example, an application) driven in the present apparatus, or UI (User Interface) and GUI (Graphic User Interface) information according to such execution screen information.

The memory 170 can store data supporting various functions of the present apparatus and programs for the operation of the processor, can store input/output data (for example, music files, still images, moving images, etc.), and can store a plurality of application programs (applications) driven in the present apparatus, data for the operation of the present apparatus, and commands. At least some of these application programs may be downloaded from an external server through wireless communication.

In addition, the memory 170 may be configured to store at least one process (or task, operation, function, control method, process, data, algorithm, program, etc.) or a processor for performing the method according to the present disclosure. Such at least one process can be performed under the control of the processor 180 and can mean information used to implement the method according to the present disclosure by the processor 180.

The memory may include at least one type of storage medium among flash memory type, hard disk type, SSD (Solid State Disk) type, SDD (Silicon Disk Drive) type, multimedia card micro type, card type memory (for example, SD or XD memory, etc.), RAM (random access memory), SRAM (static random access memory), ROM (read-only memory), EEPROM (electrically erasable programmable read-only memory), PROM (programmable read-only memory), magnetic memory, magnetic disk, and optical disk. Also, the memory may be a database that is separate from the present apparatus but connected by wire or wirelessly.

The processor 180 may be implemented as a memory for storing data regarding an algorithm for controlling operations of components in the present apparatus or a program recreating the algorithm, and at least one processor (not shown) for performing the aforementioned operations using the data stored in the memory. In this case, the memory and the processor may be implemented as separate chips, respectively. Alternatively, the memory and the processor may be implemented as a single chip.

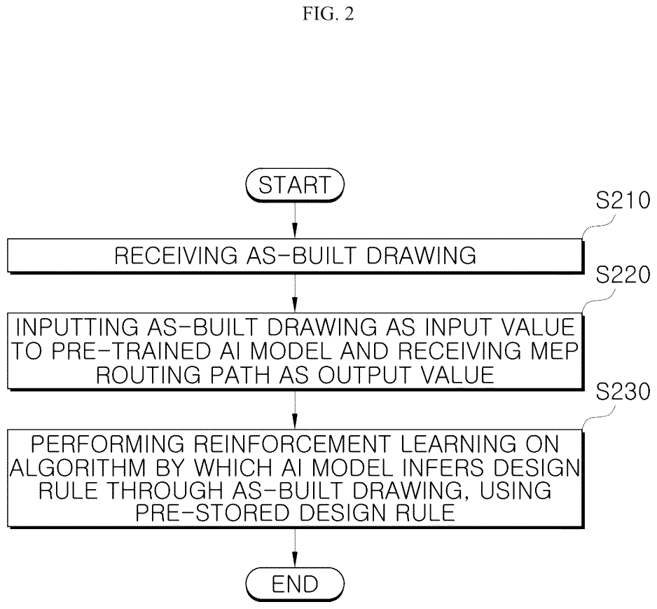

In addition, the processor may control any one or a combination of a plurality of the components described above in order to implement various embodiments according to the present disclosure described in FIGS. 2 to 9 below on the present apparatus.

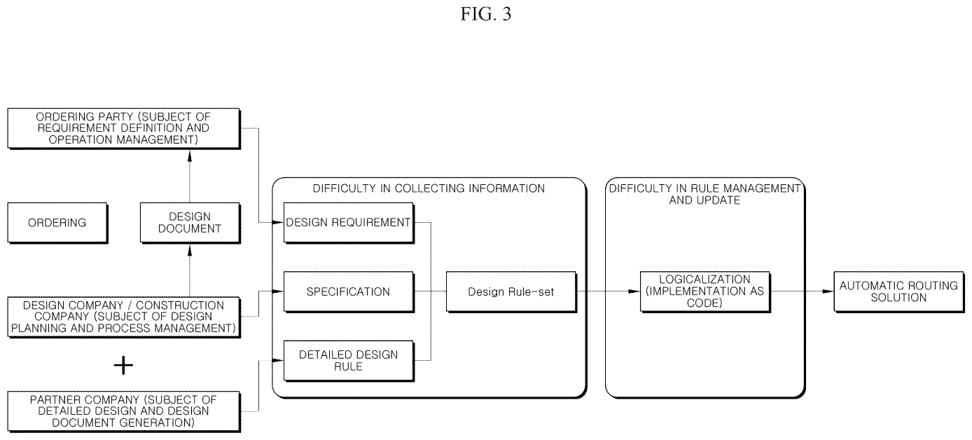

FIG. 2 is a flowchart illustrating a representative control method of the present disclosure, and FIGS. 3 to 9 are conceptual diagrams for describing the control method illustrated in FIG. 2.

Referring to FIG. 3, conventionally, a design rule-set had to be set by comprehensively considering design requirements of an ordering party, specifications of a design/construction company, and detailed design rules of a partner company, so there was difficulty in collecting information, and a logic operation for implementing this as a code had to be performed, which caused difficulty in rule management and update. That is, in order to build a conventional automatic routing solution, a process of collecting and logicalizing the know-how of companies participating in a design is required. In this case, there are various barriers in the process of all subjects providing and collecting information, and there is a problem in that continuous management is required for tasks such as conflict between logics or addition of new logic in the process of logicalizing them.

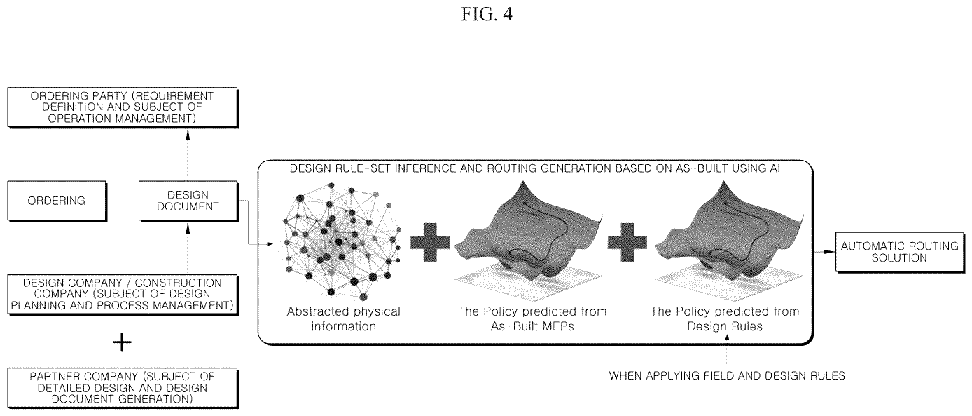

Referring to FIG. 4, the apparatus of the present disclosure provides an AI-based apparatus for generating an MEP routing path and a method for controlling the same, so that an automatic routing solution can be built without the process of FIG. 3 by utilizing an AI model.

For example, the apparatus of the present disclosure can infer a design rule through an as-built drawing using an AI model, and additionally generate an MEP routing path through reinforcement learning based on a design rule possessed by a customer (or a design/construction company, a partner company, an architect, a draftsman, etc.). That is, according to the present disclosure, the process of logicalizing the design rule can be omitted.

To this end, the apparatus 100 according to the present disclosure may include the memory 170 configured to store at least one process for performing operations of inferring a design rule and predicting an MEP routing path using an as-built drawing, and the processor 180 performing the operations of inferring the design rule and predicting the MEP routing path using the as-built drawing based on the at least one process.

Referring to FIG. 2, the processor 180 may receive an as-built drawing (S210).

The as-built drawing may mean As-Built design information or field BIM information. The as-built drawing refers to a drawing or a model that reflects the actually constructed state after a construction project is completed. Unlike initial design drawings, this includes changes or modifications and provides important information for building maintenance and additional construction.

The as-built drawing may be pre-stored in the memory 170 or may be received from an external server through the communication module 110.

Thereafter, the processor 180 may input the as-built drawing as an input value to a pre-trained AI model to receive an MEP routing path as an result value (S220).

The pre-trained AI model 182 may be the AI model 182 described above in the present specification.

The pre-trained AI model 182 may be an inference-type AI, and may be an AI model trained to output an MEP routing path as a result value when an as-built drawing is input as an input value.

Specifically, the pre-trained AI model 182 may be a model supervisedly trained using an as-built drawing dataset as training data and a ground-truth MEP routing path as a result value.

Here, the MEP routing path may mean an optimal path for machinery, electricity, or plumbing. The MEP routing path generated through the AI model in the present disclosure may mean an MEP routing path corresponding to the input as-built drawing based on the design rule inferred through the as-built drawing.

The pre-trained AI model 182 of the present disclosure may be formed to, when an as-built drawing is input, infer a design rule applied to the as-built drawing and generate an MEP routing path based on the inferred design rule.

Here, the design rule may include at least one of a design priority, a waypoint, a limit on the number of direction changes, and a length limit, and may include information on material/diameter, things to avoid and things to be grouped, the number of elbow turns or the shortest distance, expensive pipes first, fluid/gas, and the like. However, it is not limited thereto, and the design rule may vary depending on a design/construction company, a partner company, an ordering party, an architect, a draftsman, and the like.

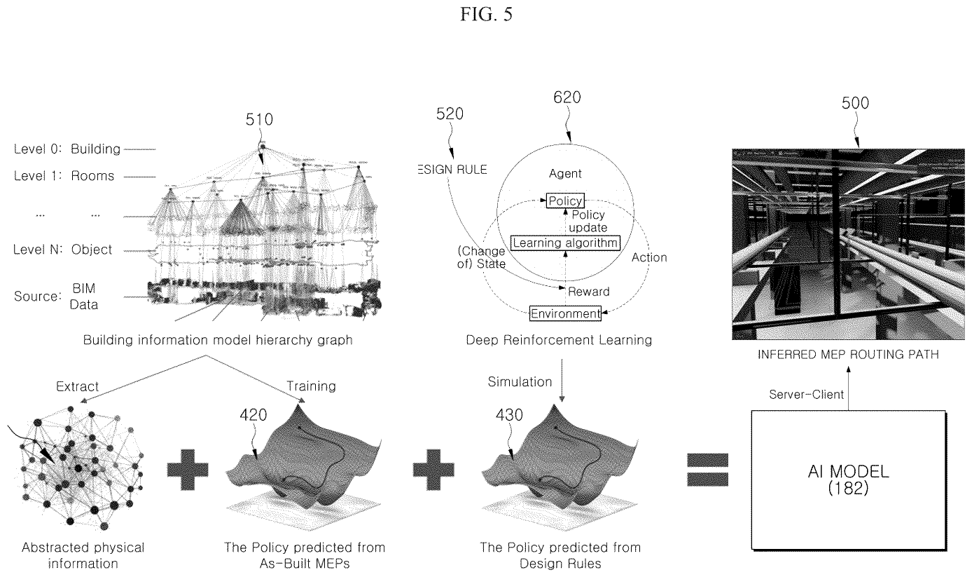

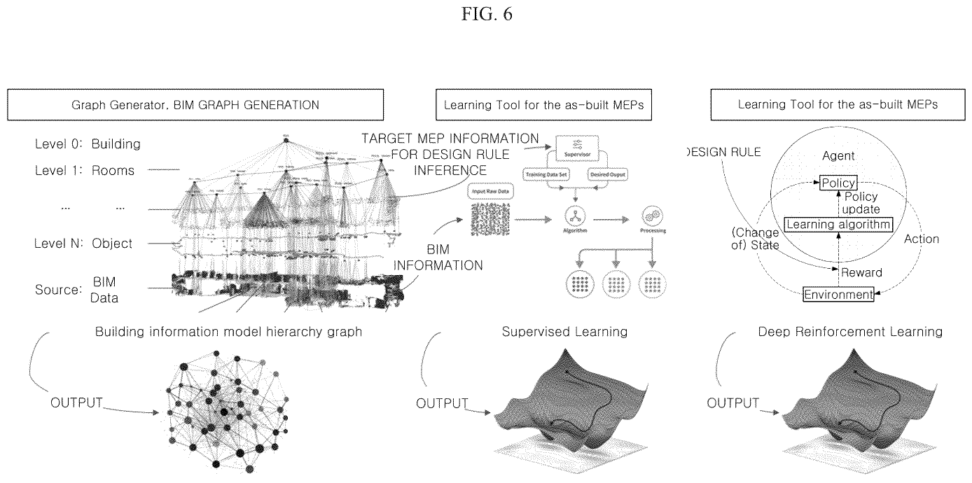

Meanwhile, referring to FIG. 5, the processor 180 of the present disclosure may include a graph generator (610, see FIG. 6) configured to convert the input as-built drawing into a graph format to be usable in the AI model 182.

The graph generator 610 may analyze an as-built drawing 510 to generate a BIM hierarchy graph 510 and input the BIM hierarchy graph as an input value to the pre-trained AI model.

The graph generator 610 may calculate abstracted physical information 410 summarized (or inferred) from the BIM hierarchy graph 510.

In addition, the processor 180 may receive a design rule inferred from the as-built drawing using the pre-trained AI model 182 (or a learning tool 620, see FIG. 6).

In addition, the processor 180 may perform reinforcement learning on an algorithm by which the AI model infers a design rule through the as-built drawing, using a pre-stored design rule (S230).

The apparatus of the present disclosure may infer a design drawing from an as-built drawing through an AI model, but when design rule information provided from a field or a workplace exists (i.e., when a pre-stored design rule exists in the memory 170), the design rule inference algorithm of the AI model can be reinforcement-learned using the pre-stored design rule.

Referring to FIG. 5, the processor 180 may perform reinforcement learning on the design rule inference algorithm of the pre-trained AI model by using an as-built drawing dataset as a training dataset and a pre-stored design rule 520 as a ground-truth value.

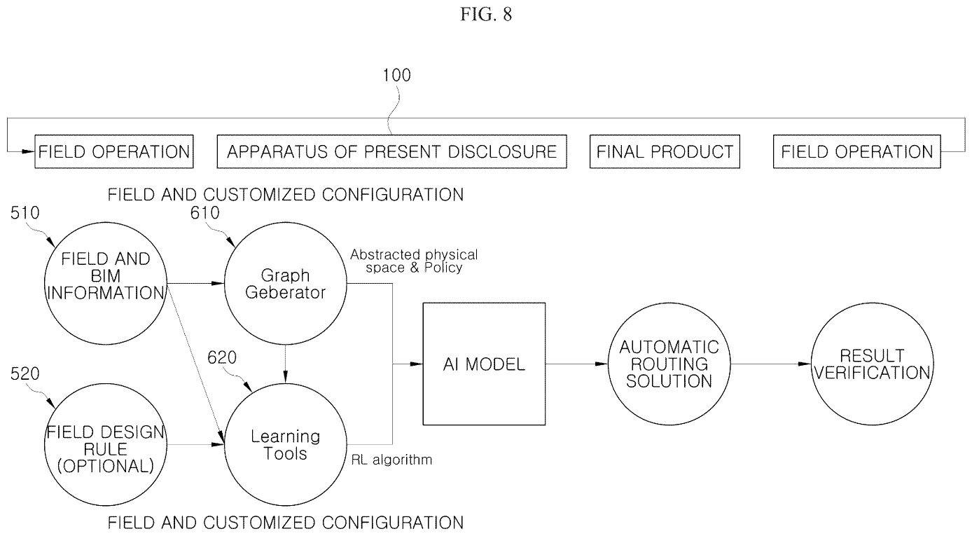

Meanwhile, the processor 180 of the present disclosure may further include a learning tool (620, see FIG. 8) that infers a design rule from an as-built drawing.

In the above description, the design rule is described as being inferred by the AI model 182, but it is not limited thereto. The apparatus of the present disclosure may be provided with separate learning tools 620, and when an as-built drawing is input through the learning tools, a design rule applied to the input as-built drawing can be inferred.

Thereafter, the processor 180 may generate (or infer, surmise, predict, or receive from the AI model 182) an MEP routing path 500 by inputting the design rule output from the learning tool 620 and the as-built drawing to the AI model 182.

Referring to FIG. 6, the apparatus 100 of the present disclosure may include the graph generator 610 converting an as-built drawing (or BIM information) into a graph format usable by the pre-trained AI model 182, the learning tool 620 trained to infer a design rule through an as-built drawing, and a reinforcement learning algorithm and learning tool (or learning tool 620) capable of learning a pre-stored design rule.

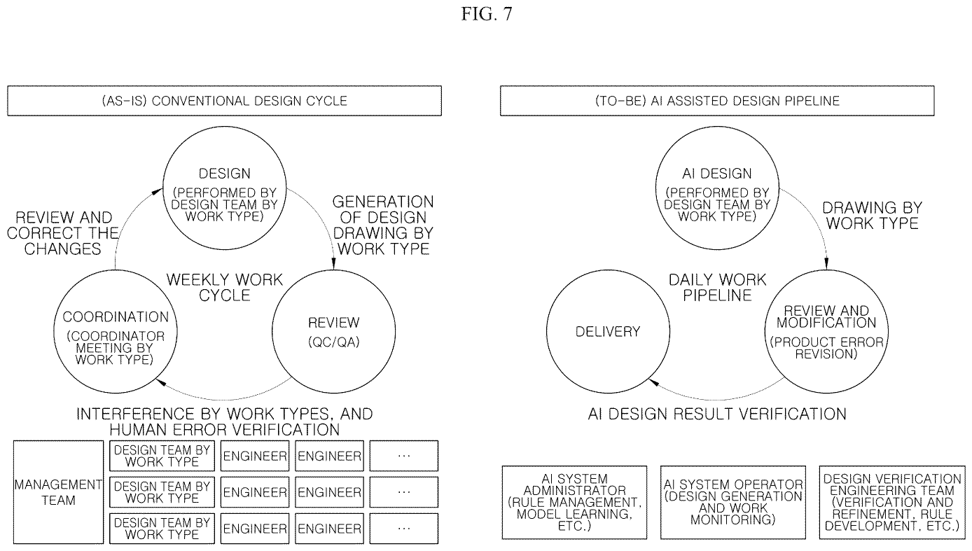

When the apparatus 100 of the present disclosure is utilized, as shown in FIG. 7, human errors occurring in a traditional design cycle and interference by work types can be minimized. In addition, by minimizing communication time such as consultation between persons in charge of different work types, the existing weekly cycle can be improved to a daily pipeline, and the size and configuration of an organization for work can be optimized.

As shown in FIG. 8, the apparatus 100 of the present disclosure can perform learning through data from a workplace and collaborate with the workplace to derive a workplace-customized automatic routing solution. When the as-built drawing (BIM information) 510 and the design rule (pre-stored design rule) 520 are provided from a workplace, the apparatus 100 of the present disclosure converts the as-built drawing into a BIM hierarchy graph that can be input to the AI model 182 through the graph generator 610 and can infer a design rule applied to the as-built drawing using the learning tool 620.

Thereafter, the apparatus 100 of the present disclosure can input the BIM hierarchy graph and the design rule to the AI model 182 and generate (receive as a result value) an MEP routing path.

In the above description, the graph generator and the learning tool have been described as separate components, but are not limited thereto. Operations/functions/control methods performed by the graph generator and the learning tool may be applied the same or similarly to the AI model 182 itself.

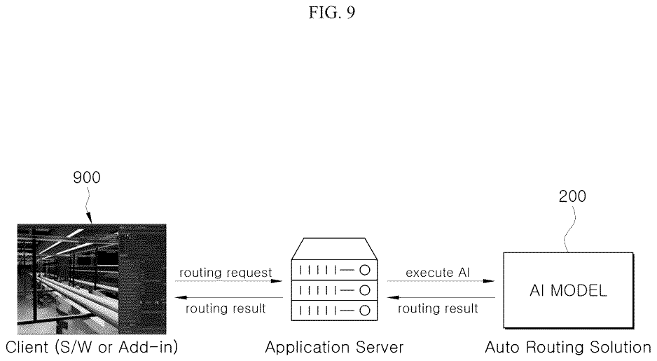

Referring to FIG. 9, the MEP routing path generated in the apparatus 100 of the present disclosure may be provided through a client 900 or software compatible with the apparatus.

The apparatus 100 of the present disclosure may be implemented in the form of an application server, and the AI model 182 may also be implemented to be provided in a separate external device.

According to the aforementioned technical solution of the present disclosure, the present disclosure can provide a new apparatus and control method capable of inferring or predicting the overall design of a new workplace by inferring a design rule using an as-built drawing.

The present disclosure can minimize human errors occurring in a traditional design cycle and interference by work types by generating an MEP routing path by inferring a design rule through an as-built drawing.

In addition, the present disclosure can improve a weekly cycle to a daily pipeline by minimizing communication time such as consultation between persons in charge of different work types, thereby further optimizing the size and configuration of an organization for work.

The effects of the present disclosure are not limited to the above-mentioned effects, and other effects not mentioned will be clearly understood by those skilled in the art from the following description.

Operations/functions/control methods performed by the AI model 182 in the present disclosure may also be understood as being performed by the processor 180.

The graph generator 610 and the learning tool 620 of the present disclosure may be a type of the AI model described in the present disclosure.

Meanwhile, the disclosed embodiments may be implemented in the form of a recording medium storing instructions executable by a computer. The instructions may be stored in the form of a program code, and when executed by a processor, may perform operations of the disclosed embodiments by generating a program module. The recording medium may be implemented as a computer-readable recording medium.

Computer-readable recording media include all kinds of recording media in which instructions that can be decoded by a computer are stored. For example, there may be ROM (Read Only Memory), RAM (Random Access Memory), magnetic tape, magnetic disk, flash memory, optical data storage device, and the like.

The disclosed embodiments have been described as above with reference to the accompanying drawings. Those skilled in the art to which the present disclosure pertains will understand that the present disclosure may be practiced in other forms different from the disclosed embodiments without changing the technical idea or essential features of the present disclosure. The disclosed embodiments are exemplary and should not be interpreted as limiting.

What is claimed is:

1. An apparatus for generating a Mechanical-Electrical-Plumbing (MEP) routing path based on artificial intelligence (AI), comprising:
at least one memory configured to store at least one process for performing operations of inferring a design rule and predicting an MEP routing path using an as-built drawing; and
a processor configured to perform the operations of inferring the design rule and predicting the MEP routing path using the as-built drawing based on the at least one process,
wherein the processor is configured to:
receive the as-built drawing;
input the as-built drawing as an input value to a pre-trained AI model and receive the MEP routing path as an output value; and
perform reinforcement learning on an algorithm by which the AI model infers the design rule through the as-built drawing, using a pre-stored design rule.

2. The apparatus of claim 1, wherein the processor comprises a graph generator configured to convert the input as-built drawing into a graph format to be usable in the AI model.

3. The apparatus of claim 2, wherein the graph generator is configured to:
analyze the as-built drawing to generate a Building Information Modeling (BIM) hierarchy graph; and
input the BIM hierarchy graph as the input value to the pre-trained AI model.

4. The apparatus of claim 3, wherein the graph generator is configured to calculate summarized physical information from the BIM hierarchy graph.

5. The apparatus of claim 3, wherein the pre-trained AI model is a model supervisedly trained using an as-built drawing dataset as training data and a ground-truth MEP routing path as a result value.

6. The apparatus of claim 5, wherein the pre-trained AI model is configured to, when the as-built drawing is input, infer a design rule applied to the as-built drawing and generate the MEP routing path based on the inferred design rule.

7. The apparatus of claim 6, wherein the design rule includes at least one of a design priority, a waypoint, a limit on the number of direction changes, and a length limit.

8. The apparatus of claim 6, wherein the processor is configured to perform reinforcement learning on a design rule inference algorithm of the pre-trained AI model by using the as-built drawing dataset as a training dataset and the pre-stored design rule as a ground-truth value.

9. The apparatus of claim 3, wherein the processor comprises a learning tool configured to infer the design rule from the as-built drawing, and is configured to input the BIM hierarchy graph output from the graph generator and the design rule inferred by the learning tool as input values to the AI model to receive the MEP routing path as the output value.

10. A method for controlling an apparatus for generating a Mechanical-Electrical-Plumbing (MEP) routing path based on artificial intelligence (AI), the method comprising:
receiving an as-built drawing;
inputting the as-built drawing as an input value to a pre-trained AI model and receiving an MEP routing path as an output value; and
performing reinforcement learning on an algorithm by which the AI model infers a design rule through the as-built drawing, using a pre-stored design rule.
